(19) United States
(12) Patent Application Publication
(10) Pub. No.: US 2015/0091662 A1
(43) Pub. Date: Apr. 2, 2015

(54) QUANTUM INTERFERENCE DEVICE, ATOMIC OSCILLATOR, ELECTRONIC APPARATUS, AND MOVING OBJECT

(71) Applicant: Seiko Epson Corporation, Tokyo (JP)

(72) Inventors: Hiroyuki YOSHIDA, Suwa (JP); Noriaki TANAKA, Chino (JP); Koji CHINDO, Suwa (JP); Tomohiro TAMURA, Suwa (JP); Yoshiyuki MAKI, Suwa (JP)

(21) Appl. No.: 14/499,766

(22) Filed: Sep. 29, 2014

(30) Foreign Application Priority Data
Sep. 30, 2013 (JP) 2013-205755

(51) Int. Cl. H03L 7/26

(52) U.S. Cl. CPC H03L 7/26
USPC 331/94.1

(57) ABSTRACT

An atomic oscillator includes a gas cell having an internal space in which alkali metal atoms are entrapped, and a light output part that outputs excitation light containing a pair of resonance lights in resonance with the alkali metal atoms toward the internal space. Further, a width of the internal space along a direction perpendicular to an axis of the excitation light is W1, a width of the excitation light along the same direction in the internal space is W2, and a relation of 40%≦W2/W1≦95% is satisfied.

### BACKGROUND

1. Technical Field

The present invention relates to a quantum interference device, an atomic oscillator, an electronic apparatus, and a moving object.

2. Related Art

Atomic oscillators that oscillate based on energy transition of alkali metals including rubidium and cesium are known as oscillators having high-accuracy oscillation characteristics on a long-term basis (for example, see JP-A-2009-164331).

Generally, the operation principle of the atomic oscillators is roughly classified into a system using a double resonance phenomenon by light and microwave and a system using a quantum interference effect (CPT: Coherent Population Trapping) by two kinds of lights having different wavelengths. The atomic oscillators using the quantum interference effect may be made smaller than the atomic oscillators using the double resonance phenomenon, and recently have been expected to be mounted on various apparatuses.

As disclosed in JP-A-2009-164331, the atomic oscillator using the quantum interference effect includes a gas cell in which gaseous metal atoms are entrapped, a semiconductor laser that applies laser beams including two kinds of resonance lights having different wavelengths to the metal atoms within the gas cell, and a light detector that detects the laser beams transmitted through the gas cell. Further, in the atomic oscillator, an electromagnetically induced transparency (EIT) phenomenon occurs that, when the frequency difference between the two kinds of resonance lights is a specific value, both of the two kinds of resonance lights are transmitted, not absorbed by the metal atoms within the gas cell, and an EIT signal as a steep signal generated with the EIT phenomenon is detected by the photodetector.

Here, in view of improvement of short-term frequency stability, it is preferable that the EIT signal has a smaller line width (half-width) and higher intensity. When the diameter of the laser beam is increased, the number of metal atoms that resonate with the laser beam is increased and the intensity of the EIT signal becomes higher. If the diameter of the laser beam is too large, the metal atoms existing near the inner wall of the gas cell that behave differently from the others resonate with the laser beam, and the line width of the EIT signal is significantly increased.

Therefore, in the atomic oscillator according to JP-A-2009-164331, the laser beam diameter is set to be as small as about 98% of the inner diameter of the gas cell.

However, in the atomic oscillator according to JP-A-2009-164331, the distance between the inner wall of the gas cell and the laser beam is too small. Accordingly, there has been a problem that optical axis adjustment when the gas cell and the semiconductor laser are installed is difficult and, if the optical axis adjustment is performed with high accuracy, then, relative displacement between the gas cell and the semiconductor laser occurs over time, the light output from the light output part travels closer to the wall surface of the internal space of the gas cell, and long-term frequency stability is degraded. For example, generally, it is considered that the gas cell and the semiconductor laser are connected via another member, the member is deformed due to thermal expansion or the like, displacement between the gas cell and the semiconductor laser occurs, and thereby, the problem is caused. Further, generally, it is considered that an optical component including a lens is provided between the gas cell and the semiconductor laser and the optical component is supported by a member other than the gas cell and the semiconductor laser, and similarly, displacement occurs and the problem is caused.

### SUMMARY

An advantage of some aspects of the invention is to provide a quantum interference device and an atomic oscillator that may exhibit advantageous short-term frequency stability and long-term frequency stability, and to provide an electronic apparatus and a moving object with advantageous reliability including the quantum interference device.

Embodiments of the invention can be implemented as the following forms or application examples.

### Application Example 1

A quantum interference device according to this application example of the invention includes a gas cell having an internal space in which metal atoms are entrapped, and a light output part that outputs light containing a pair of resonance lights for resonance with the metal atoms toward the internal space, wherein, supposing that a width of the internal space along a direction intersecting with an axis of the light is W1 and a width of the light along the intersecting direction in the internal space is W2, a relation of 40%≦W2/W1≦95% is satisfied.

According to the quantum interference device of this application example, W1 and the W2 are set as described above, and thereby, the optical axis adjustment when the gas cell and the light output part are provided becomes easier. Additionally, the advantageous short-term frequency stability can be realized by reduction of the line width of the EIT signal, and, even when the relative displacement between the gas cell and the light output part occurs over time, degradation of the long-term frequency stability due to the light output from the light output part traveling closer to the wall surface of the internal space of the gas cell can be prevented.

### Application Example 2

In the quantum interference device according to the application example described above, it is preferable that a relation of 55%≦W2/W1≦65% is satisfied.

With this configuration, even when the internal space of the gas cell is made smaller, the advantageous short-term frequency stability and long-term frequency stability can be realized relatively easily and reliably.

### Application Example 3

In the quantum interference device according to the application example described above, it is preferable that a distance between a wall surface of the internal space along the intersecting direction and the light is 0.25 mm or more.

With this configuration, even when the internal space of the gas cell is made smaller, the advantageous short-term frequency stability and long-term frequency stability can be realized relatively easily and reliably.

### Application Example 4

In the quantum interference device according to the application example described above, it is preferable that, supposing that a length of the internal space along an axis direction of the light is L1, a relation of W1<L1 is satisfied.

In the case where W1 and L1 satisfy the relation, if the difference between the width W1 and the width W2 is too small, when the relative displacement between the light output part and the gas cell occurs such that the internal space of the gas cell tilts with respect to the axis of the light output from the light output part, the light output from the light output part is more liable to travel closer to the wall surface of the internal space of the gas cell. Therefore, the above described relation between W1 and W2 is satisfied in this case, and thereby, the advantage of the invention is remarkable.

### Application Example 5

In the quantum interference device according to the application example described above, it is preferable that the W1 falls within a range from 1 mm to 10 mm.

With this configuration, downsizing of the gas cell, and thus, downsizing of the quantum interference device can be realized. Further, in the case where W1 is smaller, if the difference between the width W1 and the width W2 is too small, when the relative displacement between the gas cell and the light output part occurs over time, degradation of the long-term frequency stability due to the light output from the light output part traveling closer to the wall surface of the internal space of the gas cell is more liable to occur. Therefore, in this case, the advantage of the invention is remarkable.

### Application Example 6

In the quantum interference device according to the application example described above, it is preferable that the L1 falls within a range from 3 mm to 30 mm.

With this configuration, while the desired intensity of the EIT signal is secured, the length of the internal space along the direction in parallel to the axis of the light can be made shorter. Accordingly, even when the relative displacement between the gas cell and the light output part occurs such that the gas cell tilts with respect to the axis of the light output from the light output part, the degradation of the long-term frequency stability due to the light output from the light output part traveling closer to the wall surface of the internal space of the gas cell can be prevented.

### Application Example 7

In the quantum interference device according to the application example described above, it is preferable that a diaphragm unit for the light is provided between the light output part and the internal space.

With this configuration, the degree of freedom of design can be improved.

### Application Example 8

In the quantum interference device according to the application example described above, it is preferable that a coil that generates a magnetic field in the axis direction of the light is provided in the internal space.

With this configuration, by Zeeman splitting, gaps between the different degenerated energy levels of the metal atoms existing in the internal space can be expanded and resolution can be improved, and the line width of the EIT signal can be reduced.

### Application Example 9

In the quantum interference device according to the application example described above, it is preferable that, supposing that a radiation angle of the light output from the light output part is θ and a distance between the light output part and the gas cell is L, L×tan(θ/2) falls within a range from 0.2 mm to 5.0 mm.

With this configuration, downsizing of the quantum interference device can be realized.

### Application Example 10

An atomic oscillator according to this application example of the invention includes the quantum interference device according to the application example described above.

With this configuration, the atomic oscillator having advantageous long-term frequency stability and short-term frequency stability can be provided.

### Application Example 11

An electronic apparatus according to this application example of the invention includes the quantum interference device according to the application example described above.

With this configuration, the electronic apparatus with advantageous reliability can be provided.

### Application Example 12

A moving object according to this application example of the invention includes the quantum interference device according to the application example described above.

With this configuration, the moving object with advantageous reliability can be provided.

### BRIEF DESCRIPTION OF THE DRAWINGS

Embodiments of the invention will be described with reference to the accompanying drawings, wherein like numbers reference like elements.

FIG. 1 is a schematic diagram showing an outline configuration of an atomic oscillator according to a first embodiment of the invention.

FIG. 2 is a diagram for explanation of energy states of an alkali metal.

FIG. 3 is a graph showing a relation between a frequency difference between two lights output from a light output part and intensity of light detected in a light detection part.

FIG. 4 is an exploded perspective view of the atomic oscillator shown in FIG. 1.

FIG. 5 is a longitudinal sectional view of the atomic oscillator shown in FIG. 1.

FIG. 6 is a schematic diagram for explanation of the light output part and a gas cell of the atomic oscillator shown in FIG. 1.

FIG. 7 shows the gas cell shown in FIG. 6 from a light passage direction.

FIG. 8A is a graph showing a relation between W2/W1 and a line width (half-width) of an EIT signal, and FIG. 8B is a graph showing a relation between W2/W1 and short-term frequency stability.

FIG. 9 is a schematic diagram for explanation of a light output part and a gas cell according to a second embodiment of the invention.

FIG. 10 is a sectional view showing an atomic oscillator according to a third embodiment of the invention.

FIG. 11 is a schematic system configuration diagram when the atomic oscillator according to the invention is used for a positioning system using a GPS satellite.

FIG. 12 shows an example of a moving object according to the invention.

### DESCRIPTION OF EXEMPLARY EMBODIMENTS

Below, a quantum interference device, an atomic oscillator, an electronic apparatus, and a moving object according to the invention will be explained in detail based on embodiments shown in the accompanying drawings.

### 1. Atomic Oscillator (Quantum Interference Device)

First, an atomic oscillator according to an embodiment of the invention (the atomic oscillator including a quantum interference device) will be explained. Note that an example in which the quantum interference device according to the invention is applied to the atomic oscillator will be explained below, however, the quantum interference device according to the invention may be applied not only to the atomic oscillator but also to a magnetic sensor, a quantum memory, or the like, for example.

### First Embodiment

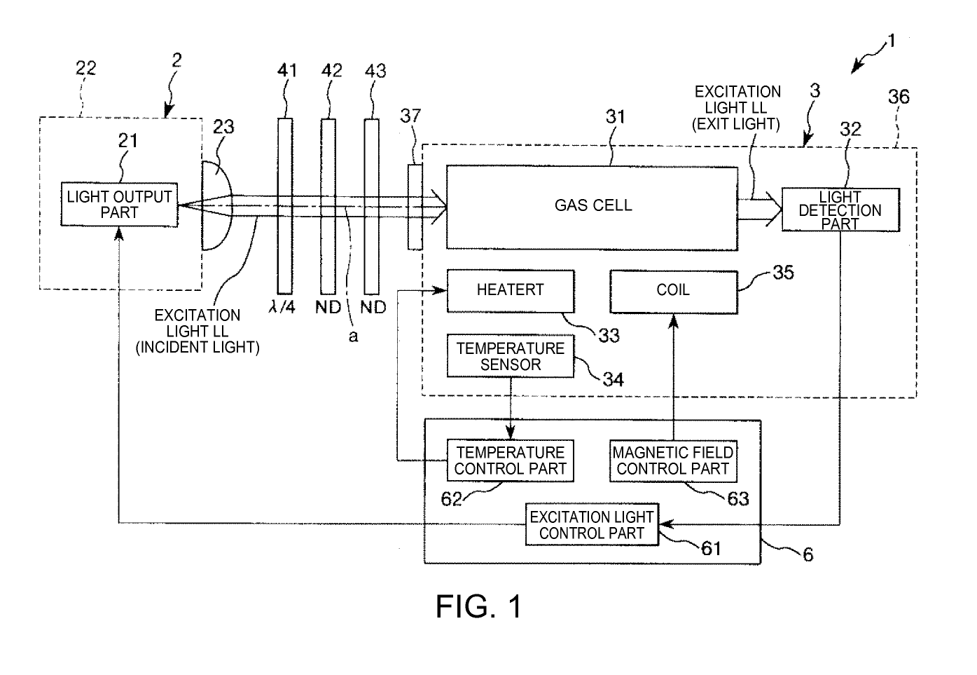

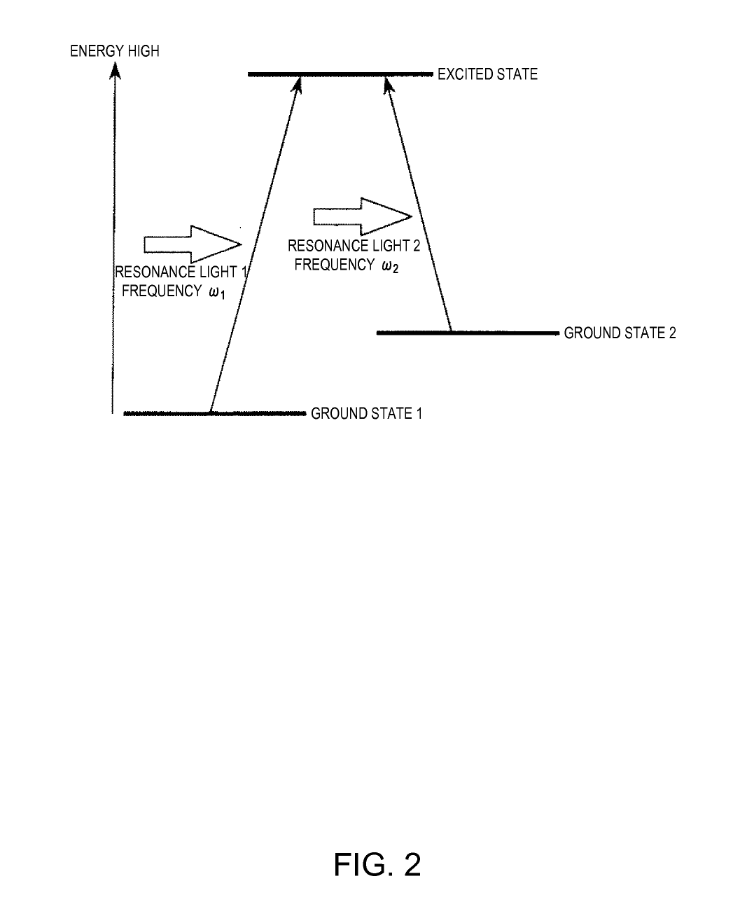

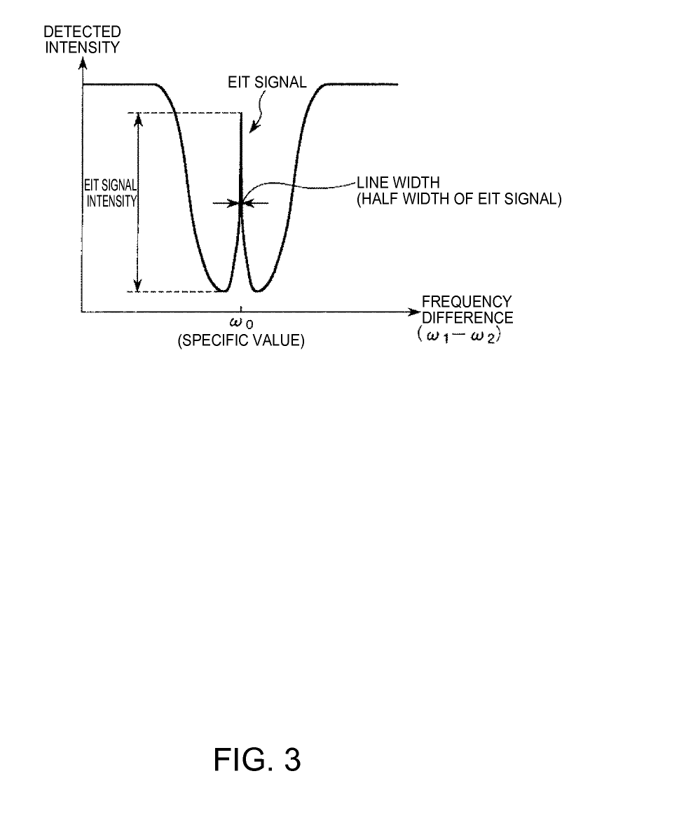

FIG. 1 is a schematic diagram showing an outline configuration of an atomic oscillator according to the first embodiment of the invention. Further, FIG. 2 is a diagram for explanation of energy states of an alkali metal, and FIG. 3 is a graph showing a relation between a frequency difference between two lights output from a light output part and intensity of light detected in a light detection part.

An atomic oscillator 1 shown in FIG. 1 is an atomic oscillator using a quantum interference effect.

As shown in FIG. 1, the atomic oscillator 1 includes a first unit 2 as a unit at the light output side, a second unit 3 as a unit at the light detection side, optical components 41, 42, 43 provided between the units 2, 3, and a control unit 6 that controls the first unit 2 and the second unit 3.

Here, the first unit 2 includes a light output part 21, and a first package 22 that houses the light output part 21.

Further, the second unit 3 includes a gas cell 31, a light detection part 32, a heater 33, a temperature sensor 34, a coil 35, and a second package 36 that houses them.

First, the principle of the atomic oscillator 1 is briefly explained.

As shown in FIG. 1, in the atomic oscillator 1, the light output part 21 outputs excitation light LL toward the gas cell 31 and the light detection part 32 detects the excitation light LL transmitted through the gas cell 31.

A gaseous alkali metal (metal atoms) is entrapped within the gas cell 31. As shown in FIG. 2, the alkali metal has energy levels of a three-level system, and may take three states of two ground states (ground states 1, 2) at different energy levels and an excited state. Here, the ground state 1 is the energy state lower than the ground state 2.

The excitation light LL output from the light output part 21 contains two kinds of resonance lights 1, 2 having different frequencies. When the two kinds of resonance lights 1, 2 are applied to the above described gaseous alkali metal, light absorptance (light transmittance) of the resonance lights 1, 2 in the alkali metal changes in response to a difference (ω1−ω2) between the frequency ω1 of the resonance light 1 and the frequency ω2 of the resonance light 2.

Further, when the difference (ω1−ω2) between the frequency ω1 of the resonance light 1 and the frequency ω2 of the resonance light 2 coincides with the frequency corresponding to the energy difference between the ground state 1 and the ground state 2, excitation from the ground states 1, 2 to the excited state is respectively stopped. In this regard, both of the resonance lights 1, 2 are transmitted through the alkali metal, and not absorbed. The phenomenon is called a CPT phenomenon or electromagnetically induced transparency (EIT).

For example, in the case where the light output part 21 fixes the frequency ω1 of the resonance light 1 and changes the frequency ω2 of the resonance light 2, when the difference (ω1−ω2) between the frequency ω1 of the resonance light 1 and the frequency ω2 of the resonance light 2 coincides with the frequency ω0 corresponding to the energy difference between the ground state 1 and the ground state 2, the detected intensity of the light detection part 32 steeply increases as shown in FIG. 3. The steep signal is detected as an EIT signal. The EIT signal has an eigenvalue with respect to each kind of alkali metal. Therefore, the oscillator may be formed using the EIT signal.

Below, the specific configuration of the atomic oscillator 1 of the embodiment will be explained.

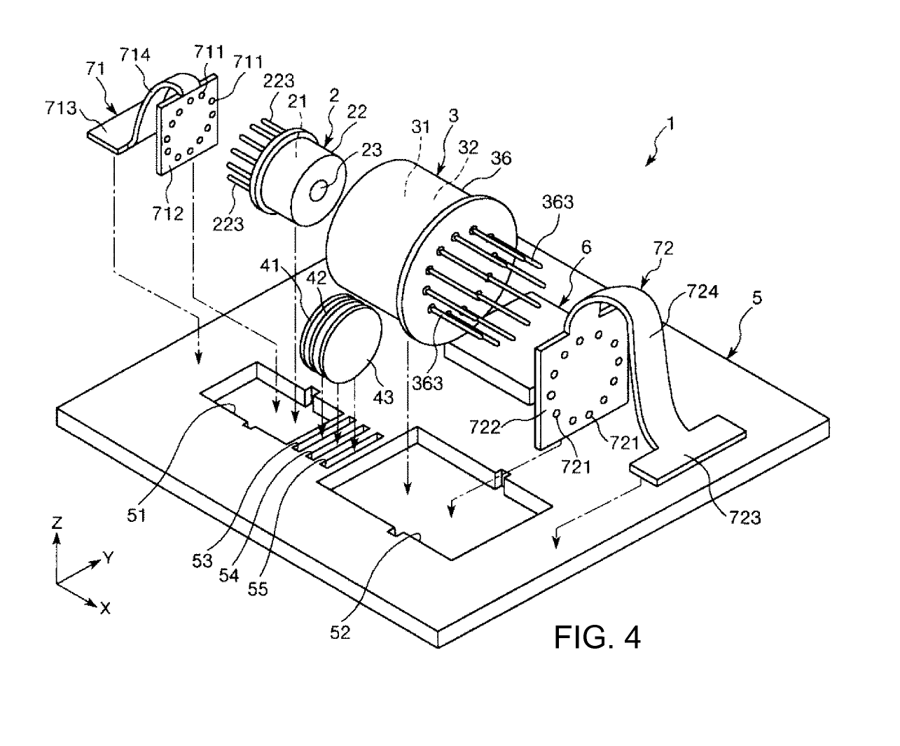

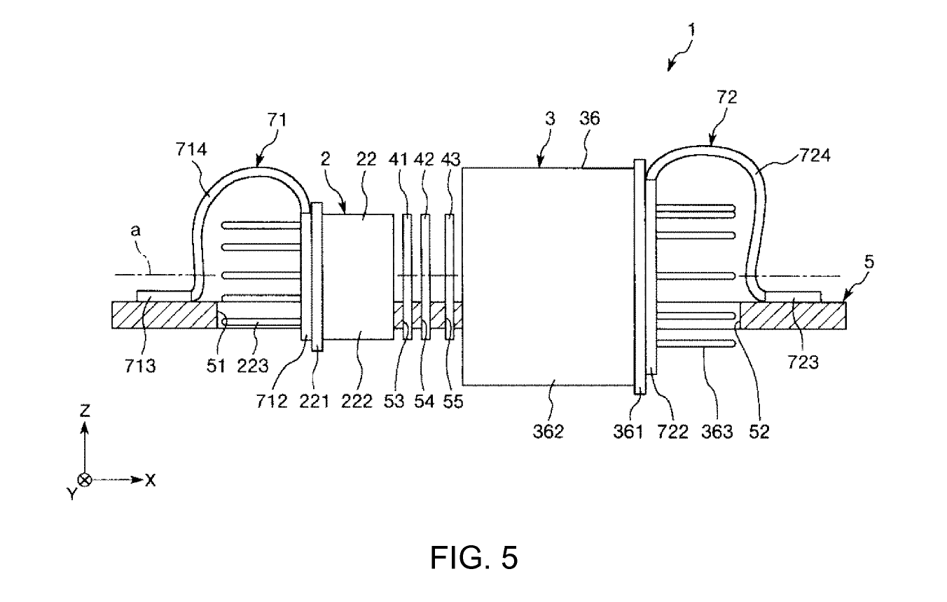

FIG. 4 is an exploded perspective view of the atomic oscillator shown in FIG. 1, and FIG. 5 is a longitudinal sectional view of the atomic oscillator shown in FIG. 1.

Note that, in FIGS. 4 and 5, for convenience of explanation, an X-axis, a Y-axis, and a Z-axis are shown as three axes orthogonal to one another, and the tip end sides of the respective arrows are referred to as “+ side” and the base end sides are referred to as “− side”. Further, below, for convenience of explanation, a direction in parallel to the X-axis is referred to as “X-axis direction”, a direction in parallel to the Y-axis is referred to as “Y-axis direction”, and a direction in parallel to the Z-axis is referred to as “Z-axis direction”, and the side in the +Z-axis direction (upside in FIG. 5) is referred to as “upper” and the side in the −Z-axis direction (downside in FIG. 5) is referred to as “lower”.

As shown in FIG. 4, the atomic oscillator 1 includes the control unit 6 mounted thereon, and includes a wiring board 5 (holding member) that holds the first unit 2, the second unit 3, and the optical components 41, 42, 43, and connectors 71, 72 that electrically connect the first unit 2, the second unit 3, and the wiring board 5.

Further, the first unit 2 and the second unit 3 are electrically connected to the control unit 6 via wiring (not shown) of the wiring board 5 and the connectors 71, 72, and drive-controlled by the control unit 6.

Below, the respective parts of the atomic oscillator 1 will be sequentially explained in detail.

### First Unit

As described above, the first unit 2 includes the light output part 21, and the first package 22 that houses the light output part 21.

### Light Output Part

The light output part 21 has a function of outputting the excitation light LL that excites the alkali metal atoms within the gas cell 31.

More specifically, the light output part 21 outputs light containing the above described two kinds of lights having different frequencies (resonance light 1 and resonance light 2) as the excitation light LL.

The frequency ω1 of the resonance light 1 may excite (resonate with) the alkali metal within the gas cell 31 from the above described ground state 1 to the excited state.

Further, the frequency ω2 of the resonance light 2 may excite (resonate with) the alkali metal within the gas cell 31 from the above described ground state 2 to the excited state.

The light output part 21 is not particularly limited as long as it may output the above described excitation light LL. For example, a semiconductor laser including a vertical cavity surface emitting laser (VCSEL) or the like may be used.

Further, the light output part 21 is temperature-adjusted to a predetermined temperature by a temperature control element (not shown) (heating resistor, Peltier element, or the like).

### First Package

The first package 22 houses the above described light output part 21.

The first package 22 includes a base member 221 (first base member) and a lid member 222 (first lid member) as shown in FIG. 5.

The base member 221 directly or indirectly supports the light output part 21. In the embodiment, the base member 221 has a plate-like shape and forms a circular shape in the plan view.

Further, the light output part 21 (mounting component) is provided (mounted) on one surface (mounting surface) of the base member 221. Further, a plurality of leads 223 project on the other surface of the base member 221 as shown in FIG. 5. The plurality of leads 223 are electrically connected to the light output part 21 via wiring (not shown).

The lid member 222 that covers the light output part 21 on the base member 221 is joined to the base member 221.

The lid member 222 has a tubular shape with an open end and a bottom. In the embodiment, the tubular shape of the lid member 222 forms a cylindrical shape.

The opening of one end of the lid member 222 is closed by the above described base member 221.

Further, a window part 23 is provided on the other end of the lid member 222, i.e., in the bottom opposite to the opening of the lid member 222.

The window part 23 is provided on the optical axis (axis a of the excitation light LL) between the gas cell 31 and the light output part 21.

Furthermore, the window part 23 has transmissivity with respect to the above described excitation light LL.

In the embodiment, the window part 23 is a lens. Thereby, the excitation light LL may be applied to the gas cell 31 without any waste.

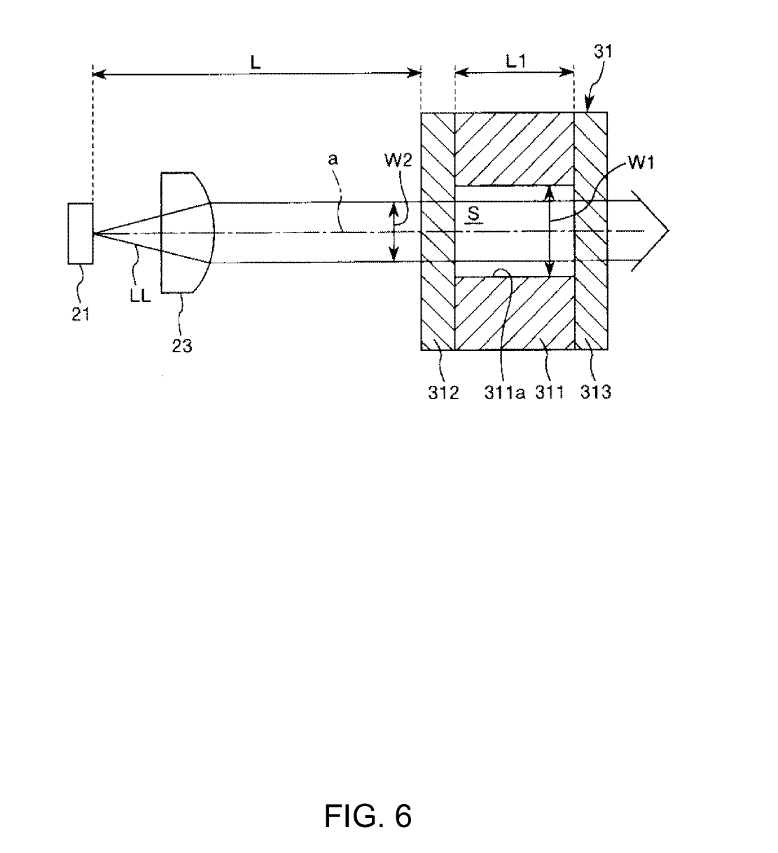

Specifically, the window part 23 as a lens has a width along a direction perpendicular to the axis a of the excitation light LL set to a width W2 smaller than a width W1 of an internal space S along the direction perpendicular to the axis a of the excitation light LL (see FIG. 6). The widths W1, W2 will be described later.

Further, the window part 23 has a function of parallelizing the excitation light LL. That is, the window part 23 is a collimator lens and the excitation light LL in the internal space S is parallel light. Thereby, the number of alkali metal atoms that resonate with the excitation light LL output from the light output part 21 of the alkali metal atoms existing in the internal space S may be increased. As a result, the intensity of the EIT signal may be increased.

Note that the window part 23 is not limited to the lens as long as it has transmissivity with respect to the excitation light LL, but may be an optical component other than the lens or a simple plate-like member having light transmissivity. In this case, for example, the lens having the above described function may be provided between the first package 22 and the second package 36 like the optical components 41, 42, 43, which will be described later.

The constituent material of the part of the lid member 222 other than the window part 23 is not particularly limited, but e.g., ceramics, metal, resin, or the like may be used.

Here, when the part of the lid member 222 other than the window part 23 is formed using a material having transmissivity with respect to the excitation light, the part of the lid member 222 other than the window part 23 and the window part 23 may be integrally formed. Further, when the part of the lid member 222 other than the window part 23 is formed using a material having no transmissivity with respect to the excitation light, the part of the lid member 222 other than the window part 23 and the window part 23 may be separately formed and they may be joined by a known joining method.

Further, it is preferable that the base member 221 and the lid member 222 are air-tightly joined. That is, it is preferable that the interior of the first package 22 is an airtight space. Thereby, the interior of the first package 22 may be decompressed or filled with an inertia gas and, as a result, the characteristics of the atomic oscillator 1 may be improved.

Furthermore, the method of joining the base member 221 and the lid member 222 is not particularly limited, but, e.g., soldering, seam welding, energy beam welding (laser welding, electron beam welding, etc.), or the like may be used.

Note that a joining member for joining them may intervene between the base member 221 and the lid member 222.

Further, a component other than the above described light output part 21 may be housed within the first package 22.

For example, a temperature adjustment element, a temperature sensor, or the like that adjusts the temperature of the light output part 21 may be housed within the first package 22. The temperature adjustment element includes, e.g., a heating resistor (heater) and a Peltier element.

According to the first package 22 having the base member 221 and the lid member 222, the light output part 21 may be housed within the first package 22 while allowing output of the excitation light from the light output part 21 to the outside of the first package 22.

Further, the first package 22 is held by the wiring board 5, which will be described later, so that the base member 221 may be provided at the opposite side to the second package 36.

### Second Unit

As described above, the second unit 3 includes the gas cell 31, the light detection part 32, the heater 33, the temperature sensor 34, the coil 35, and the second package 36 that houses them.

### Gas Cell

The alkali metal of gaseous rubidium, cesium, sodium, or the like is entrapped within the gas cell 31. Further, a rare gas including argon and neon or an inertia gas including nitride may be entrapped as a buffer gas with the alkali metal gas within the gas cell 31 as desired.

For example, as shown in FIG. 6, the gas cell 31 has a main body part 311 having a columnar through hole 311a, and a pair of window parts 312, 313 that seal both openings of the through hole 311a. Thereby, the above described internal space S in which the alkali metal is entrapped is formed.

The material forming the main body part 311 is not particularly limited, but includes a metal material, a resin material, a glass material, a silicon material, and crystal. In view of processability and joining to the window parts 312, 313, the glass material or silicon material may be preferably used.

The window parts 312, 313 are air-tightly jointed to the main body part 311. Thereby, the internal space S of the gas cell 31 may be formed as the airtight space.

The joining method between the main body part 311 and the window parts 312, 313 is determined according to their constituent materials, but not particularly limited. For example, a joining method using an adhesive, direct bonding, anodic bonding, or the like may be employed.

Further, the constituent material of the window parts 312, 313 is not particularly limited as long as it has transmissivity with respect to the above described excitation light LL, but includes, e.g., a silicon material, a glass material, and crystal.

The respective window parts 312, 313 have transmissivity with respect to the above described excitation light LL from the light output part 21. The excitation light LL entering the gas cell 31 is transmitted through one window part 312 and the excitation light LL output from the gas cell 31 is transmitted through the other window part 313.

In the gas cell 31, the width W1 of the internal space S along the direction perpendicular to (intersecting with) the axis a of the excitation light LL is larger than the width W2 along the direction perpendicular to the axis a of the excitation light LL (see FIG. 6). The widths W1, W2 will be described later in detail.

Further, the gas cell 31 is heated and temperature-adjusted to a predetermined temperature by the heater 33.

### Light Detection Part

The light detection part 32 has a function of detecting the intensity of the excitation light LL (resonance lights 1, 2) transmitted in the gas cell 31.

The light detection part 32 is not particularly limited as long as it may detect the above described excitation light. For example, a solar cell, a photodetector (light receiving element) including a photodiode may be employed.

### Heater

The heater 33 has a function of heating the above described gas cell 31 (more specifically, the alkali metal in the gas cell 31). Thereby, the alkali metal in the gas cell 31 may be maintained in the gas state at desired concentration.

The heater 33 generates heat by energization, and includes, e.g., a heating resistor provided on the outer surface of the gas cell 31. The heating resistor may be formed using, e.g., chemical vapor deposition (CVD) including plasma CVD and thermal CVD, dry plating including vacuum deposition, a sol-gel process, or the like.

Here, when provided in the entrance part or the output part of the excitation light LL in the gas cell 31, the heating resistor is formed using a material having transmissivity with respect to the excitation light, specifically, e.g., a transparent electrode material of oxide including ITO (Indium Tin Oxide), IZO (Indium Zinc Oxide), In₃O₃, SnO₂, SnO₂ containing Sb, or ZnO containing Al.

Note that the heater 33 is not particularly limited as long as it may heat the gas cell 31, but may be contactless with respect to the gas cell 31. Furthermore, the gas cell 31 may be heated using a Peltier element in place of the heater 33, or, in conjunction with the heater 33.

The heater 33 is electrically connected to a temperature control part 62 of the control unit 6, which will be described later, for energization control.

### Temperature Sensor

The temperature sensor 34 detects the temperature of the heater 33 or the gas cell 31. Further, the amount of generated heat by the above described heater 33 is controlled based on the detection result of the temperature sensor 34. Thereby, the alkali metal atoms within the gas cell 31 may be maintained at a desired temperature.

Note that the location where the temperature sensor 34 is provided is not particularly limited, but may be provided, e.g., on the heater 33 or on the outer surface of the gas cell 31.

The temperature sensor 34 is not particularly limited, but various kinds of known temperature sensors including a thermistor and a thermocouple may be employed.

The temperature sensor 34 is electrically connected to the temperature control part 62 of the control unit 6, which will be described later, via wiring (not shown).

### Coil

The coil 35 has a function of generating a magnetic field in the direction (parallel direction) along the axis a of the excitation light LL in the internal space S. Thereby, by Zeeman splitting, gaps between the different degenerated energy levels of the alkali metal atoms existing in the internal space S may be expanded and resolution may be improved, and the line width of the EIT signal may be reduced.

Note that the magnetic field generated by the coil may be a direct-current magnetic field or an alternating-current magnetic field, or a magnetic field obtained by superimposing the direct-current magnetic field and the alternating-current magnetic field.

The location where the coil 35 is provided is not particularly limited, but the coil may be provided by being wound along the outer circumference of the gas cell 31 to form a solenoid type or a pair of coils may be opposed via the gas cell 31 to form a Helmholtz type.

The coil 35 is electrically connected to a magnetic field control part 63 of the control unit 6, which will be described later, via wiring (not shown). Thereby, the coil 35 may be energized.

### Second Package

The second package 36 houses the above described gas cell 31, light detection part 32, heater 33, temperature sensor 34, and coil 35.

The second package 36 has the same configuration as the above described first package 22 of the first unit 2.

Specifically, as shown in FIG. 5, the second package 36 includes a base member 361 (second base member) and a lid member 362 (second lid member).

The base member 361 directly or indirectly supports the gas cell 31, the light detection part 32, the heater 33, the temperature sensor 34, and the coil 35. In the embodiment, the base member 361 has a plate-like shape and forms a circular shape in the plan view.

Further, the gas cell 31, the light detection part 32, the heater 33, the temperature sensor 34, and the coil 35 (a plurality of mounting components) are provided (mounted) on one surface (mounting surface) of the base member 361. Further, a plurality of leads 363 project on the other surface of the base member 361 as shown in FIG. 5. The plurality of leads 363 are electrically connected to the light detection part 32, the heater 33, the temperature sensor 34, and the coil 35 via wiring (not shown).

The lid member 362 that covers the gas cell 31, the light detection part 32, the heater 33, the temperature sensor 34, and the coil 35 on the base member 361 is joined to the base member 361.

The lid member 362 has a tubular shape with an open end and a bottom. In the embodiment, the tubular shape part of the lid member 362 forms a cylindrical shape.

The opening of one end of the lid member 362 is closed by the above described base member 361.

Further, a window part 37 is provided on the other end of the lid member 362, i.e., in the bottom opposite to the opening of the lid member 362.

The window part 37 is provided on the optical axis (axis a) between the gas cell 31 and the light output part 21.

Further, the window part 37 has transmissivity with respect to the above described excitation light.

In the embodiment, the window part 37 is formed by a plate-like member having light transmissivity.

Note that the window part 37 is not particularly limited to the plate-like member having light transmissivity as long as it has transmissivity with respect to the excitation light, but may be an optical component including e.g., a lens, a polarizer, a λ/4-plate (herein, λ/4 means ¼ wavelength).

The constituent material of the part of the lid member 362 other than the window part 37 is not particularly limited, but e.g., ceramics, metal, resin, or the like may be used.

Here, when the part of the lid member 362 other than the window part 37 is formed using a material having transmissivity with respect to the excitation light, the part of the lid member 362 other than the window part 37 and the window part 37 may be integrally formed. Further, when the part of the lid member 362 other than the window part 37 is formed using a material having no transmissivity with respect to the excitation light, the part of the lid member 362 other than the window part 37 and the window part 37 may be separately formed and they may be joined by a known joining method.

Further, it is preferable that the base member 361 and the lid member 362 are air-tightly joined. That is, it is preferable that the interior of the second package 36 is an airtight space. Thereby, the interior of the second package 36 may be decompressed or filled with an inertia gas and, as a result, the characteristics of the atomic oscillator 1 may be improved.

Furthermore, the method of joining the base member 361 and the lid member 362 is not particularly limited, but, e.g., soldering, seam welding, energy beam welding (laser welding, electron beam welding, etc.), or the like may be used.

Note that a joining member for joining them may intervene between the base member 361 and the lid member 362.

Further, it is desirable that at least the gas cell 31 and the light detection part 32 are housed within the second package 36, or a component other than the above described gas cell 31, light detection part 32, heater 33, temperature sensor 34, and the coil 35 may be housed.

According to the second package 36 having the base member 361 and the lid member 362, the gas cell 31 and the light detection part 32 may be housed within the second package 36 while allowing entry of the excitation light from the light output part 21 into the second package 36. Therefore, the second package 36 is used in combination with the above described first package 22, and thereby, the light output part 21 and the gas cell 31 may be housed in the contactless separate packages from each other while the optical path of the excitation light from the light output part 21 via the gas cell 31 to the light detection part 32 is secured.

Further, the second package 36 is held by the wiring board 5, which will be described later, so that the base member 361 may be provided at the opposite side to the first package 22.

### Optical Components

The plurality of optical components 41, 42, 43 are respectively provided between the above described first package 22 and second package 36. The plurality of optical components 41, 42, 43 are respectively provided along the optical axis (axis a) between the light output part 21 within the above described first package 22 and the gas cell 31 within the above described second package 36.

Further, in the embodiment, they are provided in the order of the optical component 41, the optical component 42, and the optical component 43 from the first package 22 side to the second package 36 side.

The optical component 41 is a λ/4-wave plate. Thereby, for example, when the excitation light from the light output part 21 is linearly-polarized light, the excitation light may be converted into circularly-polarized light (right circularly-polarized light or left circularly-polarized light).

As described above, under a condition that the alkali metal atoms within the gas cell 31 are Zeeman-split by the magnetic field of the coil 35, if the linearly-polarized excitation light is applied to the alkali metal atoms, by the interaction between the excitation light and the alkali metal atoms, the alkali metal atoms are Zeeman-split and uniformly distributed at a plurality of levels. As a result, the number of alkali metal atoms at a desired energy level is smaller than the numbers of alkali metal atoms at the other energy levels, and thus, the number of atoms that exhibit a desired EIT phenomenon decreases and the desired EIT signal becomes smaller. As a result, the oscillation characteristics of the atomic oscillator 1 are degraded.

On the other hand, as described above, under the condition that the alkali metal atoms within the gas cell 31 are Zeeman-split by the magnetic field of the coil 35, if the circularly-polarized excitation light is applied to the alkali metal atoms, by the interaction between the excitation light and the alkali metal atoms, of a plurality of levels at which the alkali metal atoms are Zeeman-split, the number of alkali metal atoms at a desired energy level may be made larger than the numbers of alkali metal atoms at the other energy levels. Accordingly, the number of atoms that exhibit a desired EIT phenomenon increases and the desired EIT signal becomes larger. As a result, the oscillation characteristics of the atomic oscillator 1 may be improved.

In the embodiment, the optical component 41 has a circular plate shape. Accordingly, the optical component 41 may be rotated around the axis line in parallel to the optical axis (axis a) while being engaged with a through hole 53 having a shape, which will be described later. Note that the planar shape of the optical component 41 is not limited to that, but may be, e.g., a polygonal shape including square and pentagon.

The optical components 42, 43 are provided at the second unit 3 side with respect to the optical component 41.

The optical components 42, 43 are respectively neutral density filters (ND filters). Thereby, the intensity of the excitation light LL entering the gas cell 31 may be adjusted (reduced). Accordingly, even when the output of the light output part 21 is larger, an amount of the excitation light entering the gas cell 31 may be a desired amount of light. In the embodiment, the intensity of the excitation light converted into the circularly-polarized light by the above described optical component 41 is adjusted by the optical components 42, 43.

In the embodiment, the optical components 42, 43 respectively have plate shapes. Further, the planar shapes of the optical components 42, 43 respectively have circular shapes. Accordingly, the optical components 42, 43 may be respectively rotated around the axis line in parallel to the optical axis (axis a) while being engaged with the through hole 53 having the shape, which will be described later.

Note that the planar shapes of the optical components 42, 43 are not limited to those, but may be, e.g., polygonal shapes including square and pentagon.

The optical component 42 and the optical component 43 may have equal dimming rates to each other or not.

Further, the optical components 42, 43 may respectively have portions having continuously or gradually different dimming rates between the upper parts and the lower parts. In this case, the vertical locations of the optical components 42, 43 with respect to the wiring board 5 are adjusted, and thereby, the dimming rate of the excitation light may be adjusted.

Furthermore, the optical components 42, 43 may respectively have portions having continuously or gradually different dimming rates along the circumferential direction. In this case, the optical components 42, 43 are rotated, and thereby, the dimming rate of the excitation light may be adjusted. Note that, in this case, the rotation centers of the optical components 42, 43 should be shifted with respect to the axis a.

Note that one optical component of the optical components 42, 43 may be omitted. Further, when the output of the light output part 21 is adequate, both of the optical components 42, 43 may be omitted.

Furthermore, the optical components 41, 42, 43 are not limited to the above described types, the order of arrangement, the numbers, or the like. For example, the optical components 41, 42, 43 are respectively not limited to the λ/4-wave plate or the neutral density filters, but may be lenses, polarizers, or the like.

### Wiring Board

The wiring board 5 has wiring (not shown), and has a function of electrically connecting the electronic components including the control unit 6 mounted on the wiring board 5 and the connectors 71, 72.

Further, the wiring board 5 has a function of holding the above described first package 22, second package 36, and plurality of optical components 41, 42, 43.

The wiring board 5 holds the first package 22 and the second package 36 under a non-contact condition with each other via a space. Thereby, thermal interference between the light output part 21 and the gas cell 31 may be prevented or suppressed and the temperature control of the light output part 21 and the gas cell 31 may be independently and accurately performed.

Specifically, as shown in FIG. 4, in the wiring board 5, through holes 51, 52, 53, 54, 55 penetrating in its thickness direction are formed.

Here, the through hole 51 (first through hole) is provided at one end side of the wiring board 5 in the X-axis direction, and the through hole 52 (second through hole) is provided at the other end side of the wiring board 5 in the X-axis direction. Further, the through holes 53, 54, 55 (third through holes) are provided between the through hole 51 and the through hole 52 of the wiring board 5.

In the embodiment, the through holes 51, 52, 53, 54, 55 are formed independently of one another. Accordingly, rigidity of the wiring board 5 may be made advantageous.

Further, a part of the first package 22 is inserted from upside into the through hole 51, and thereby, the first package 22 is positioned with respect to the wiring board 5 in the X-axis direction, the Y-axis direction, and the Z-axis direction.

In the embodiment, the width of the through hole 51 in the Y-axis direction is smaller than the width of the first package 22 in the Y-axis direction (the diameter of the tubular part). Accordingly, the first package 22 engages (contacts) with the edge part of the through hole 51 under the condition that the center axis of the tubular part is located above with respect to the wiring board 5.

Further, the first package 22 is brought into contact with the edge part of the through hole 51, and the contact area between the first package 22 and the wiring board 5 may be made smaller. Thereby, heat transfer between the first package 22 and the wiring board 5 may be suppressed.

Similarly, a part of the second package 36 is inserted into the through hole 52 and the second package 36 is positioned with respect to the wiring board 5 in the X-axis direction, the Y-axis direction, and the Z-axis direction. Further, like the first package 22, the second package 36 is brought into contact with the edge part of the through hole 52, and the contact area between the second package 36 and the wiring board 5 may be made smaller. Thereby, heat transfer between the second package 36 and the wiring board 5 may be suppressed.

As described above, the heat transfer between the first package 22 and the second package 36 via the wiring board 5 may be suppressed, and the thermal interference between the light output part 21 and the gas cell 31 may be suppressed.

According to the wiring board 5 having the through holes 51, 52, the first package 22 and the second package 36 are provided on the wiring board 5, and thereby, positioning of the optical system including the light output part 21 and the light detection part 32 may be performed. Accordingly, the first package 22 and the second package 36 may be easily provided with respect to the wiring board 5.

Further, compared to the case where a member holding the first package 22 and the second package 36 is separately provided from the wiring board 5, the number of parts may be reduced. As a result, reduction in cost and size of the atomic oscillator 1 may be realized.

Furthermore, in the embodiment, as described above, the through hole 51 into which the first package 22 is inserted and the through hole 52 into which the second package 36 is inserted are individually formed in the wiring board 5, and thus, the first package 22 and the second package 36 may be held by the wiring board 5 with the advantageous rigidity of the wiring board 5.

In addition, a part of the optical component 41 is inserted into the through hole 53, and thereby, the optical component 41 is positioned with respect to the wiring board 5 in the X-axis direction, the Y-axis direction, and the Z-axis direction.

Similarly, a part of the optical component 42 is inserted into the through hole 54, and thereby, the optical component 42 is positioned with respect to the wiring board 5 in the X-axis direction, the Y-axis direction, and the Z-axis direction.

Further, a part of the optical component 43 is inserted into the through hole 55, and thereby, the optical component 43 is positioned with respect to the wiring board 5 in the X-axis direction, the Y-axis direction, and the Z-axis direction.

According to the wiring board 5 having the through holes 53, 54, 55, the optical components 41, 42, 43 are respectively held. Thus, when the respective parts of the wiring board 5 are attached at manufacturing of the atomic oscillator 1, the optical components 41, 42, 43 may be provided on the wiring board with adjustment of the locations or positions while the first package 22 and the second package 36 are held by the wiring board 5.

The through hole 53 may rotatably hold the optical component 41 around the axis line (e.g., axis a) along the line segment connecting the first package 22 and the second package 36. Thereby, the optical component 41 is engaged with the through hole 53 of the wiring board 5 and positioned in the direction in parallel to the axis a, and the position of the optical component 41 around the axis a may be adjusted.

Similarly, the through hole 54 may rotatably hold the optical component 42 around the axis line along the line segment connecting the first package 22 and the second package 36. Further, the through hole 55 may rotatably hold the optical component 43 around the axis line along the line segment connecting the first package 22 and the second package 36.

In the embodiment, the through holes 53, 54, 55 are formed so that the plate surfaces of the optical components 41, 42, 43 may be in parallel to one another. Further, the through holes 53, 54, 55 are formed so that the plate surfaces of the optical components 41, 42, 43 may be respectively perpendicular to the axis a. Note that the through holes 53, 54, 55 may be formed so that the plate surfaces of the optical components 41, 42, 43 may not be in parallel to one another, or so that the plate surfaces of the optical components 41, 42, 43 may be respectively tilted with respect to the axis a.

Here, as described above, the optical component 41 is the λ/4-wave plate, and thus, the excitation light from the light output part 21 may be converted from the linearly-polarized light into the circularly-polarized light by adjusting the position of the optical component 41 by rotation regardless of the position of the first package 22 with respect to the wiring board 5.

When the optical components 41, 42, 43 are provided on the wiring board 5, for example, first, the first unit 2 and the second unit 3 are provided and fixed onto the wiring board 5. Then, the optical components 41, 42, 43 are engaged with the respective corresponding through holes 53, 54, 55, and at least ones of the locations and the positions of the optical components 41, 42, 43 are changed while the EIT signal or the like are confirmed. Then, when the desired EIT signal is confirmed, the respective optical components 41, 42, 43 are fixed to the wiring board 5 under the condition. The fixation is not particularly limited, but, e.g., a photo-curable adhesive is preferably used. Before being cured, even when the photo-curable adhesive is supplied to the respective through holes 53, 54, 55, the locations or positions of the respective optical components 41, 42, 43 may be changed, and the adhesive may be cured for fixation in a shorter time as desired.

As the wiring board 5, various kinds of printed wiring boards may be used. In view of securement of rigidity desired for maintenance of the location relations between the first package 22, the second package 36 and the optical components 41, 42, 43 held as described above, it is preferable to use a board having a rigid part, e.g., a rigid substrate, a rigid flexible board, or the like.

Note that, even in the case where a wiring board without a rigid part (e.g., a flexible board) is used as the wiring board 5, for example, a reinforcement member for improvement of rigidity is joined to the wiring board, and thereby, the location relations between the first package 22, the second package 36 and the optical components 41, 42, 43 may be maintained.

The control unit 6 and the connectors 71, 72 are provided on one surface of the wiring board 5. Note that other electronic components than the control unit 6 may be mounted on the wiring board 5.

### Control Unit

The control unit 6 shown in FIG. 1 has a function of respectively controlling the heater 33, the coil 35, and the light output part 21.

In the embodiment, the control unit 6 includes an IC (Integrated Circuit) chip mounted on the wiring board 5.

The control unit 6 has an excitation light control part 61 that controls the frequencies of the resonance lights 1, 2 of the light output part 21, the temperature control part 62 that controls the temperature of the alkali metal in the gas cell 31, and the magnetic field control part 63 that controls the magnetic field applied to the gas cell 31.

The excitation light control part 61 controls the frequencies of the resonance lights 1, 2 output from the light output part 21 based on the detection result of the above described light detection part 32. More specifically, the excitation light control part 61 controls the frequencies of the resonance lights 1, 2 output from the light output part 21 so that the above described frequency difference (ω1−ω2) may be the frequency ω0 unique to the alkali metal based on the detection result of the above described light detection part 32.

Further, the excitation light control part 61 includes a voltage-controlled crystal oscillator (oscillation circuit) (not shown), and synchronizes and adjusts the oscillation frequency of the voltage-controlled crystal oscillator based on the sensing result of the light detection part 32 and outputs an output signal of the atomic oscillator 1.

Furthermore, the temperature control part 62 controls energization to the heater 33 based on the detection result of the temperature sensor 34. Thereby, the gas cell 31 may be maintained within a desired temperature range.

In addition, the magnetic field control part 63 controls energization to the coil 35 so that the magnetic field generated by the coil 35 may be constant.

### Connectors

The connector 71 (first connector) is attached to the first package 22 and has a function of electrically connecting the light output part 21 and the wiring board 5. Thereby, the light output part 21 within the first package 22 is electrically connected to the control unit 6 via the connector 71.

Further, the connector 72 (second connector) is attached to the second package 36 and has a function of electrically connecting the light detection part 32 and the wiring board 5. Thereby, the light detection part 32, the heater 33, the temperature sensor 34, and the coil 35 within the second package 36 are electrically connected to the control unit 6 via the connector 72.

As shown in FIG. 4, the connector 71 includes a connector portion 712 attached to the first package 22, a fixed portion 713 fixed to the wiring board 5, and a cable portion 714 that connects the connector portion 712 and the fixed portion 713.

The connector portion 712 has a sheet shape and a plurality of through holes 711 penetrating in its thickness direction.

The plurality of through holes 711 are provided in correspondence with the plurality of leads 223 of the first package 22. In the plurality of through holes 711, the plurality of leads 223 are inserted in correspondence with each other.

The plurality of leads 223 are respectively fixed to the connector portion 712 as shown in FIG. 5 using e.g., solder or the like, and electrically connected to wiring (not shown) provided in the connector portion 712.

On the other hand, the fixed portion 713 has a sheet shape and fixed to the wiring board 5 as shown in FIG. 5 using e.g., an anisotropic conducting adhesive (ACF) or the like, and wiring (not shown) provided in the fixed portion 713 is electrically connected to the wiring (not shown) of the above described wiring board 5.

Further, the wiring (not shown) of the fixed portion 713 is electrically connected to the wiring (not shown) of the connector portion 712 via wiring (not shown) provided in the cable portion 714.

Like the above described connector 71, as shown in FIG. 4, the connector 72 includes a connector portion 722 attached to the second package 36, a fixed portion 723 fixed to the wiring board 5, and a cable portion 724 that connects the connector portion 722 and the fixed portion 723.

The connector portion 722 has a sheet shape and a plurality of through holes 721 penetrating in its thickness direction.

The plurality of through holes 721 are provided in correspondence with the plurality of leads 363 of the second package 36. In the plurality of through holes 721, the plurality of leads 363 are inserted in correspondence with each other.

The plurality of leads 363 are respectively fixed to the connector portion 722 as shown in FIG. 5 using e.g., solder or the like, and electrically connected to wiring (not shown) provided in the connector portion 722.

On the other hand, the fixed portion 723 has a sheet shape and fixed to the wiring board 5 as shown in FIG. 5 using e.g., an anisotropic conducting adhesive (ACF) or the like, and wiring (not shown) provided in the fixed portion 723 is electrically connected to the wiring (not shown) of the above described wiring board 5.

Further, the wiring (not shown) of the fixed portion 723 is electrically connected to the wiring (not shown) of the connector portion 722 via wiring (not shown) provided in the cable portion 724.

The connectors 71, 72 respectively include flexible boards. That is, in the connector 71, the connector portion 712, the fixed portion 713, and the cable portion 714 are respectively formed by flexible boards, and the connector portion 712, the fixed portion 713, and the cable portion 714 are integrally formed. Similarly, in the connector 72, the connector portion 722, the fixed portion 723, and the cable portion 724 are respectively formed by flexible boards, and the connector portion 722, the fixed portion 723, and the cable portion 724 are integrally formed.

The connectors 71, 72 including the flexible boards are used, and thereby, reduction in size and cost of the atomic oscillator 1 may be realized.

Note that the electrical connection between the light output part 21 and the wiring board 5 and the electrical connection between the light detection part 32 and the wiring board 5 are respectively not limited to the above described connectors 71, 72, but the connector portions may have e.g., socket shapes.

Widths W1, W2

The configurations of the respective parts of the atomic oscillator 1 have been explained, and the widths W1, W2 will be described in detail.

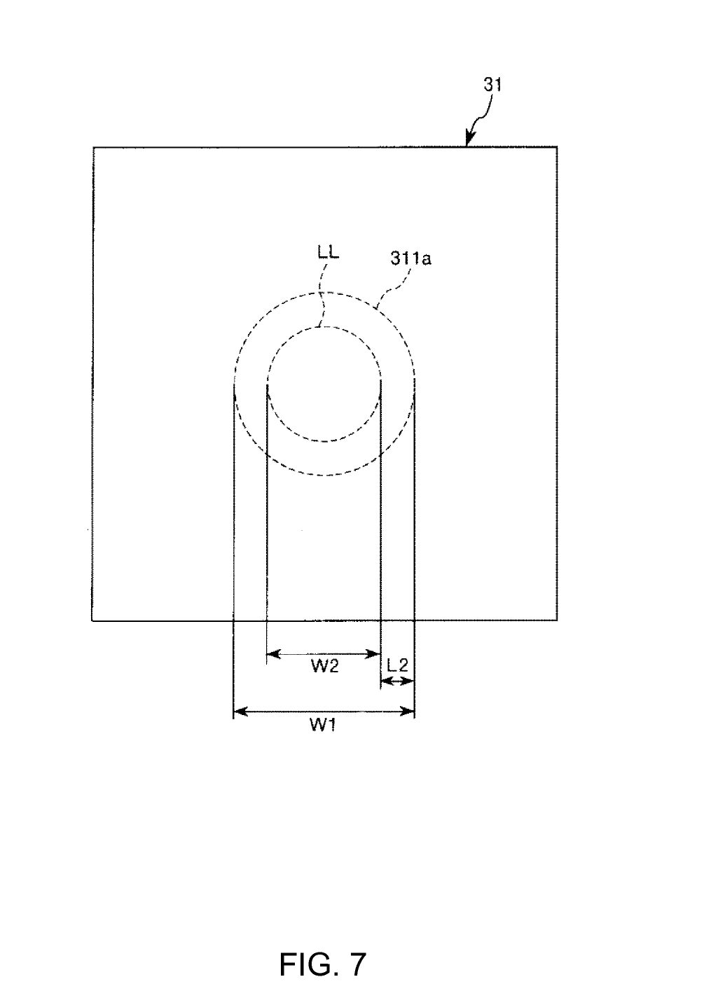

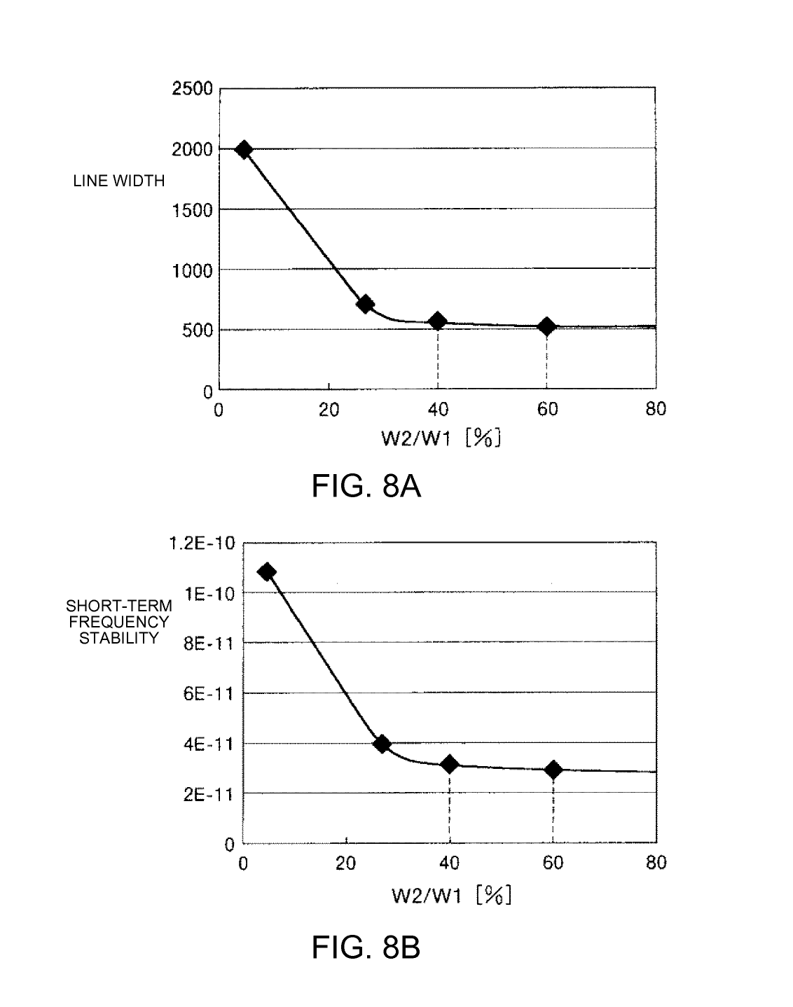

FIG. 6 is a schematic diagram for explanation of the light output part and the gas cell of the atomic oscillator shown in FIG. 1, and FIG. 7 shows the gas cell shown in FIG. 6 from a light passage direction. Further, FIG. 8A is a graph showing a relation between W2/W1 and a line width (half-width) of the EIT signal, and FIG. 8B is a graph showing a relation between W2/W1 and short-term frequency stability.

In the atomic oscillator 1, as shown in FIGS. 6 and 7, supposing that the width of the internal space S along the direction perpendicular to the axis a of the excitation light LL is W1 (hereinafter, also simply referred to as “width W1”) and the width of the excitation light LL along the same direction in the internal space S is W2 (hereinafter, also simply referred to as “width W2”), the relation of 40% W2/W1≦95% is satisfied.

With the widths W1 and the W2 set as described above, the optical axis adjustment when the gas cell 31 and the light output part 21 are provided becomes easier. Additionally, the advantageous short-term frequency stability may be realized by reduction of the line width of the EIT signal, and, even when the relative displacement between the gas cell 31 and the light output part 21 occurs over time, degradation of the long-term frequency stability due to the excitation light LL output from the light output part 21 traveling closer to the wall surface of the internal space S of the gas cell 31 may be prevented.

More specifically, W2/W1 is set to 40% or higher, and thereby, as shown in FIG. 8A, the line width of the EIT signal is smaller. As a result, as shown in FIG. 8B, the short-term frequency stability becomes higher.

Here, in the atomic oscillator 1, the gas cell 31 and the light output part 21 are not directly connected, but connected via another member including the wiring board 5. Accordingly, for example, strain of the wiring board 5 causes displacement between the gas cell 31 and the light output part 21. Therefore, when the difference between the width W1 and the width W2 is smaller, the excitation light LL output from the light output part 21 is more liable to be applied to the alkali metal behaving differently from others existing near the wall surface of the internal space S of the gas cell 31.

Accordingly, W2/W1 is set to 95% or lower, and thereby, the distance between the inner wall of the internal space S and the excitation light LL becomes larger. Even when displacement among the light output part 21, the gas cell 31, the window part 23, and the like occurs, the application of the excitation light LL output from the light output part 21 to the alkali metal behaving differently from the others existing near the wall surface of the internal space S of the gas cell 31 may be prevented. Therefore, increase of the line width of the EIT signal with the displacement may be prevented and, as a result, the advantageous long-term frequency stability may be exhibited.

On the other hand, when W2/W1 is too small, as shown in FIG. 8A, the line width of the EIT signal sharply increases and, as a result, as shown in FIG. 8B, the short-term frequency stability is degraded. Or, when W2/W1 is too large, the distance between the inner wall of the internal space S and the excitation light LL becomes extremely smaller. Even when the displacement among the light output part 21, the gas cell 31, the window part 23, occurs, the excitation light LL output from the light output part 21 is applied to the alkali metal behaving differently from the others existing near the wall surface of the internal space S of the gas cell 31. Therefore, increase of the line width of the EIT signal with the displacement occurs and, as a result, the long-term frequency stability may be degraded.

Note that FIGS. 8A and 8B are obtained by obtaining the respective line widths and the short-term frequency stability when the width W2 (diameter) of the excitation light LL is 0.2 mm, 1.2 mm, 1.8 mm, 2.7 mm in the case where the section shape of the internal space S along the direction perpendicular to the axis a is a circular shape and the width W1 (diameter) is 4.5 mm, and the inventors have confirmed that the same advantage is obtained even when the widths W1, W2 fall within other ranges.

Further, while W2/W1 satisfies the above described range, it is preferable that the ratio satisfies a relation of 55%≦W2/W1≦65%. Thereby, even when the internal space S of the gas cell 31 becomes smaller, the advantageous short-term frequency stability and long-term frequency stability may be realized relatively easily and reliably.

Furthermore, the distance L2 between the wall surface of the internal space S along the direction perpendicular to the axis a of the excitation light LL and the excitation light LL is preferably 0.25 mm or larger, more preferably from 0.25 mm to 1.35 mm, and even more preferably from 0.5 mm to 1.2 mm. Thereby, even when the internal space S of the gas cell 31 becomes smaller, the advantageous short-term frequency stability and long-term frequency stability may be realized relatively easily and reliably.

Supposing that the length of the internal space S along the direction in parallel to the axis a of the excitation light LL (along the axis a of the excitation light LL) is L1, it is preferable that the relation of W1<L1 is satisfied. Thereby, the number of alkali metals subjected to application of the excitation light LL may be increased and the intensity of the EIT signal may be made larger. Further, in the case where W1 and L1 satisfy the relation, if the difference between the width W1 and the width W2 is too small, when the relative displacement between the gas cell 31 and the light output part 21 occurs such that the internal space S of the gas cell 31 tilts with respect to the axis a of the excitation light LL output from the light output part 21, the excitation light LL output from the light output part 21 is more liable to travel closer to the wall surface of the internal space S of the gas cell 31. Therefore, the above described relation between W1 and W2 is satisfied in this case, and thereby, the advantage of the invention is remarkable.

Further, the width W1 preferably falls within a range from 1 mm to 10 mm, more preferably within a range from 2 mm to 8 mm, and even more preferably within a range from 3 mm to 6 mm. Thereby, downsizing of the gas cell 31, and thus, downsizing of the atomic oscillator 1 may be realized. In the case where W1 is smaller, if the difference between the width W1 and the width W2 is too small, when the relative displacement between the gas cell 31 and the light output part 21 occurs over time, degradation of the long-term frequency stability due to the light output from the light output part 21 traveling closer to the wall surface of the internal space S of the gas cell 31 is more liable to occur. Therefore, in this case, the advantage of the invention is remarkable.

Furthermore, the length L1 of the internal space S along the direction in parallel to the axis a of the excitation light LL preferably falls within a range from 3 mm to 30 mm, more preferably within a range from 4 mm to 25 mm, and even more preferably within a range from 5 mm to 20 mm. Thereby, while the desired intensity of the EIT signal is secured, the length L1 of the internal space S along the direction in parallel to the axis a of the excitation light LL may be made shorter. Accordingly, even when the relative displacement between the gas cell 31 and the light output part 21 occurs such that the gas cell 31 tilts with respect to the axis a of the excitation light LL output from the light output part 21, the degradation of the long-term frequency stability due to the excitation light LL output from the light output part 21 traveling closer to the wall surface of the internal space S of the gas cell 31 may be prevented.

In addition, in the embodiment, both of the cross section shapes of the internal space S along the direction perpendicular to the axis of the excitation light LL and the excitation light LL are circular shapes. The cross section shapes of the internal space S and the excitation light LL have the similarity shapes, and the excitation light LL may be efficiently applied to the alkali metal atoms in the internal space S. Note that the cross section shapes of the internal space S and the excitation light LL may be different from each other, are not limited to the circular shapes, but may be polygonal shapes including e.g., triangular shapes, square shapes, and pentagonal shapes, oval shapes, or the like.

Further, supposing that the radiation angle of the excitation light LL output from the light output part 21 is θ and the distance between the light output part 21 and the gas cell 31 is L, it is preferable that L×tan(θ/2) falls within a range from 0.2 mm to 5.0 mm. Thereby, downsizing of the atomic oscillator 1 may be realized.

### Second Embodiment

The second embodiment of the invention will be explained.

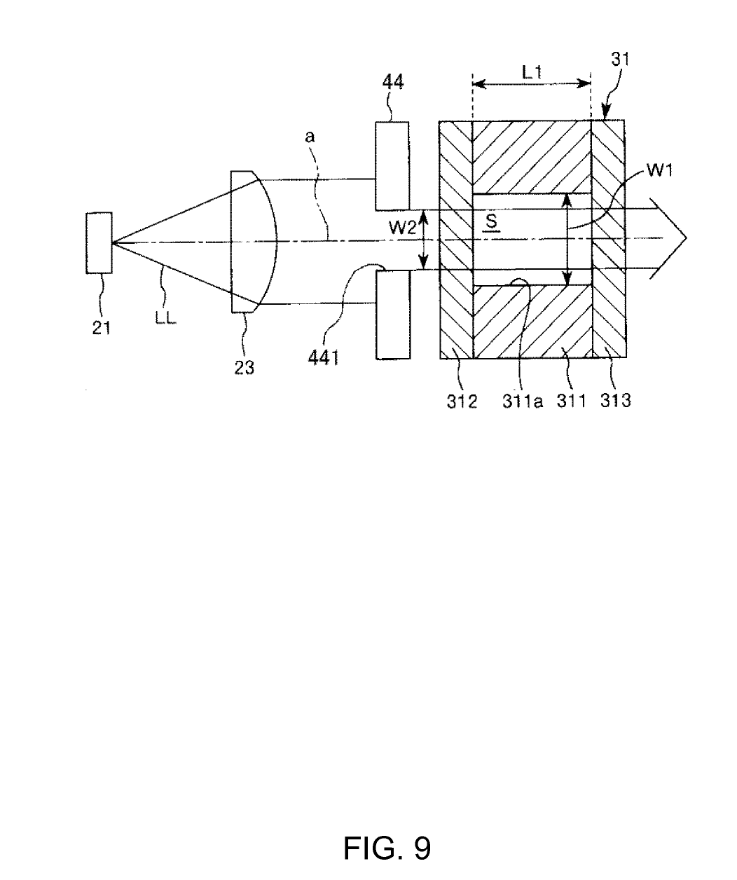

FIG. 9 is a schematic diagram for explanation of a light output part and a gas cell according to the second embodiment of the invention.

The embodiment is the same as the above described first embodiment except that the light output from the light output part is shaped using a diaphragm.

Note that, in the following explanation, the second embodiment will be explained with a focus on the difference from the above described embodiment, and the explanation of the same items will be omitted. Further, in FIG. 9, the same configurations as those of the above described embodiment have the same signs.

As shown in FIG. 9, in the embodiment, a diaphragm 44 (diaphragm unit) having an aperture 441 is provided between the window part 23 (lens) and the gas cell 31.

The diaphragm 44 shapes the excitation light LL as the parallel light through the window part 23 to the width W2. The diaphragm 44 is used, and thereby, the degree of freedom of design such as the arrangement of the light output part 21 and the window part 23, the radiation angle of the excitation light LL of the light output part 21, the lens power of the window part 23, may be improved.

According to the above explained second embodiment, the widths W1, W2 are set like those in the first embodiment, and advantageous short-term frequency stability and long-term frequency stability may be exhibited.

### Third Embodiment

The third embodiment of the invention will be explained.

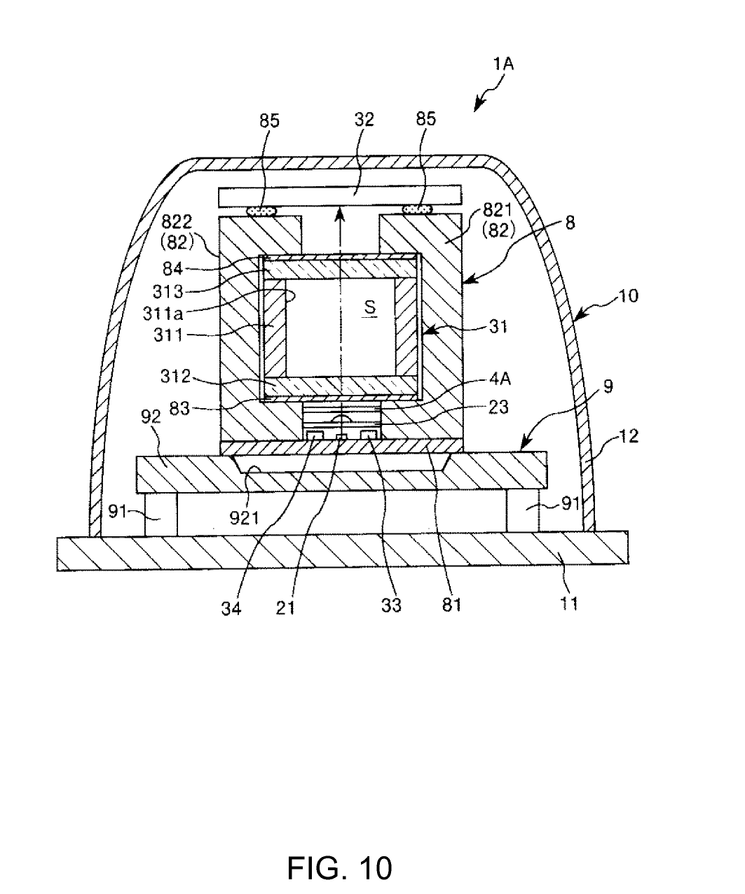

FIG. 10 is a sectional view showing an atomic oscillator according to the third embodiment of the invention.

The atomic oscillator according to the embodiment is the same as the atomic oscillator according to the above described first embodiment except that a plurality of component parts including the light output part and the gas cell are housed within one package.

Note that, in the following explanation, the atomic oscillator of the third embodiment will be explained with a focus on the difference from the first embodiment, and the explanation of the same items will be omitted. Further, in FIG. 10, the same configurations as those of the above described embodiment have the same signs.

An atomic oscillator 1A shown in FIG. 10 includes a unit section 8 forming a main part that generate a quantum interference effect, a package 10 that houses the unit section 8, and a support member 9 (support part) housed within the package 10 and supporting the unit section 8 with respect to the package 10.

Here, the unit section 8 includes the gas cell 31, the light output part 21, an optical component 4A, the light detection part 32, the heater 33 (heat generation part), the temperature sensor 34, a substrate 81, and a connecting member 82, and they are unitized. Note that the optical component 4A is a combination of the optical components 41, 42, 43 of the above described first embodiment. Further, though not illustrated in FIG. 10, the atomic oscillator 1A further has the coil 35 and the control unit 6.

In the unit section 8, heat from the heater 33 is transferred to the gas cell 31 via the substrate 81 and the connecting member 82.

The light output part 21, the heater 33, the temperature sensor 34, and the connecting member 82 are mounted on one surface (upper surface) of the substrate 81.

The substrate 81 has a function of transferring the heat from the heater 33 to the connecting member 82. Thereby, even when the heater 33 is separated from the connecting member 82, the heat from the heater 33 may be transferred to the connecting member 82.

Here, the substrate 81 thermally connects the heater and the connecting member 82. The heater 33 and the connecting member 82 are mounted on the substrate 81, and thereby, the degree of freedom of the installation of the heater 33 may be improved.

Further, the light output part 21 is mounted on the substrate 81, and thereby, the light output part 21 may be temperature-adjusted by the heat from the heater 33.

The constituent material of the substrate 81 is not particularly limited, but a material with advantageous heat conductivity, e.g., a metal material may be used. Note that, when the substrate 81 is formed using a metal material, an insulating layer formed using, e.g., a resin material, metal oxide, metal nitride, or the like may be provided on the surface of the substrate 81 as desired.

Note that the substrate 81 may be omitted depending on the shape of the connecting member 82, the location where the heater 33 is provided, or the like. In this case, the heater may be provided in the location in contact with the connecting member 82.

The connecting member 82 includes a pair of connecting members 821, 822 provided with the gas cell 31 in between. Further, the connecting member 82 is formed using a material with advantageous thermal conductivity, e.g., a metal material.

The connecting member 82 thermally connects the heater 33 and the respective window parts 312, 313 of the gas cell 31. Thereby, the heat from the heater 33 may be transferred to the respective window parts 312, 313 via thermal conduction by the connecting member 82 to heat the respective window parts 312, 313. Further, the heater 33 and the gas cell 31 may be separated. Accordingly, an adverse effect on the metal atoms within the gas cell 31 by an unnecessary magnetic field generated by the energization to the heater 33 may be suppressed. Furthermore, the number of heaters 33 may be reduced and, for example, the number of wires for energization to the heater 33 is reduced. As a result, downsizing of the atomic oscillator 1A (quantum interference device) may be realized.

In the embodiment, a heat transfer layer 83 is provided on the outer surface of the window part 312 of the gas cell 31. Similarly, a heat transfer layer 84 is provided on the outer surface of the window part 313 of the gas cell 31.

The heat transfer layers 83, 84 are respectively formed using materials having higher coefficients of thermal conductivity than the coefficients of thermal conductivity of the materials forming the respective window parts 312, 313. Thereby, the heat from the connecting member 82 may be efficiently diffused via the heat conduction by the heat transfer layers 83, 84. As a result, temperature distributions of the respective window parts 312, 313 may be homogenized.

Further, the heat transfer layers 83, 84 have transmissivity for the excitation light. Thereby, the excitation light may be allowed to enter the gas cell 31 via the heat transfer layer 83 and the window part 312 from outside of the gas cell 31. The excitation light may be allowed to output from inside of the gas cell 31 via the heat transfer layer 84 and the window part 313 to the outside of the gas cell 31.

The constituent materials of the heat transfer layers 83, 84 are not particularly limited as long as they have the higher coefficients of thermal conductivity than the coefficients of thermal conductivity of the materials forming the respective window parts 312, 313 and the heat transfer layers 83, 84 can transmit the excitation light. For example, diamond, DLC (diamond-like carbon), or the like may be used.

Note that the heat transfer layers 83, 84 may be omitted.

Further, the light detection part 32 is joined onto the connecting member 82 via adhesives 85.

The above described unit section 8 is supported by the package 10 via the support member 9.

The package 10 has a function of housing the unit section 8 and the support member 9. Note that, in FIG. 10, though not illustrated, the coil 35 is also housed within the package 10. Further, other parts than the above described parts may be housed within the package 10.

The package 10 includes a plate-like base member 11 (base part) and a tubular lid member 12 having a bottom, and the opening of the lid member 12 is sealed by the base member 11. Thereby, the space for housing the unit section 8 and the support member 9 is formed.

The base member 11 supports the unit section 8 via the support member 9.

Further, though not illustrated, a plurality of wires and a plurality of terminals for energization from outside of the package 10 to the unit section 8 inside are provided on the base member 11.

The constituent material of the base member 11 is not particularly limited, but, e.g., a resin material, a ceramics material, or the like may be used.

The lid member 12 is joined to the base member 11.

The method of joining the base member 11 and the lid member 12 is not particularly limited, but, e.g., soldering, seam welding, energy beam welding (laser welding, electron beam welding, etc.) or the like may be used.

Note that a joining member for joining them may intervene between the base member 11 and the lid member 12.

The constituent material of the lid member 12 is not particularly limited, but, e.g., a resin material, a ceramics material, a metal material, or the like may be used.

Further, it is preferable that the base member 11 and the lid member 12 are air-tightly joined. That is, it is preferable that the interior of the package 10 is an airtight space. Thereby, the interior of the package 10 may be decompressed or filled with an inertia gas and, as a result, the characteristics of the atomic oscillator 1A may be improved.

Particularly, it is preferable that the interior of the package 10 is decompressed. Thereby, heat transfer via the space within the package 10 may be suppressed. Accordingly, thermal interference between the connecting member 82 and the outside of the package 10 or between the heater 33 and the gas cell 31 via the space within the package 10 may be suppressed. Thus, the heat from the heater 33 may be efficiently transferred to the respective window parts 312, 313 via the connecting member 82, and thereby, the temperature difference between the two window parts 312, 313 may be suppressed. Further, heat transfer between the unit section 8 and the outside of the package 10 may be suppressed more effectively.

The support member 9 (support part) is housed within the package 10 and has a function of supporting the unit section 8 with respect to the base member 11 forming a part of the package 10.

Further, the support member 9 has a function of suppressing the heat transfer between the unit section 8 and the outside of the package 10.

The support member 9 has a plurality of leg potions 91 (columnar portions) and a coupling part 92 that couples the plurality of leg potions 91.

The plurality of leg potions 91 are respectively joined to the surface inside of the base member 11 of the package 10 using e.g., an adhesive.

The plurality of leg potions 91 are provided outside of the unit section 8 in a plan view as seen from a direction in which the base member 11 and the unit section 8 overlap (hereinafter, simply referred to as “plan view”). Thereby, even when the distance between the base member 11 and the unit section 8 is made shorter, the heat transfer path from the unit section 8 to the base member 11 via the support member 9 may be made longer.

The coupling part 92 couples the upper ends (the other ends) of the plurality of leg portions 91. Thereby, rigidity of the support member 9 is improved. In the embodiment, the coupling part 92 is integrally formed with the plurality of leg portions 91. Note that the coupling part 92 may be formed separately from the plurality of leg portions 91 and, for example, may be joined to the respective leg portions 91 using an adhesive.

The unit section 8 (more specifically, the substrate 81) is joined (connected) to the upper surface of the coupling part 92 (the surface opposite to the leg portions 91). Thereby, the unit section 8 is supported by the support member 9.

Further, a recessed portion 921 is formed at the center of the upper surface of the coupling part 92 (i.e., the surface at the unit section 8 side). The space within the recessed portion 921 is located between the unit section 8 and the coupling part 92. Thereby, the contact area between the unit section 8 and the coupling part 92 may be reduced and the heat transfer between the coupling part 92 and the unit section 8 may be effectively suppressed. Further, heat transfer in the coupling part 92 may be suppressed.

The constituent material of the support member 9 is not particularly limited as long as it has relatively low heat conductivity and the support member 9 can secure rigidity for supporting the unit section 8. For example, a nonmetal such as a resin material or a ceramics material is preferably used, and a resin material is more preferably used. In the case where the support member 9 is formed using a resin material, even when the shape of the support member 9 is complex, the support member 9 may be easily manufactured using a known method such as injection molding, for example. Note that the constituent material of the leg portions 91 and the constituent material of the coupling part 92 may be the same or different.

According to the above explained third embodiment, the widths W1, W2 are set like those in the first embodiment, and advantageous short-term frequency stability and long-term frequency stability may be exhibited.

### 2. Electronic Apparatus

The above described atomic oscillators may be incorporated into various kinds of electronic apparatuses. The electronic apparatuses have advantageous reliability.

Below, an electronic apparatus according to an embodiment of the invention will be explained.

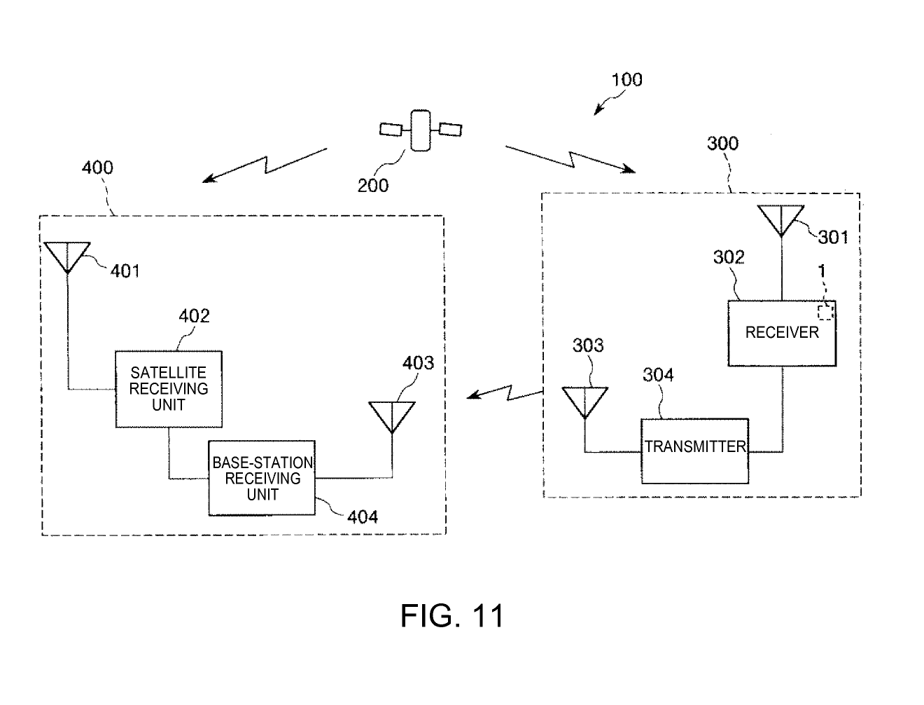

FIG. 11 is a schematic configuration diagram when the atomic oscillator according to the invention is used for a positioning system using a GPS satellite.

A positioning system 100 shown in FIG. 11 includes a GPS satellite 200, a base station apparatus 300, and a GPS receiving apparatus 400.

The GPS satellite 200 transmits positioning information (GPS signals).

The base station apparatus 300 includes a receiver 302 that precisely receives the positioning information from the GPS satellite 200 via an antenna 301 installed in an electronic reference point (GPS continuous observation station), and a transmitter 304 that transmits the positioning information received by the receiver 302 via an antenna 303.

Here, the receiver 302 is an electronic device including the above described atomic oscillator according to the invention as a reference frequency oscillation source thereof. The receiver 302 has advantageous reliability. Further, the positioning information received by the receiver 302 is transmitted by the transmitter 304 in real time.

The GPS receiving apparatus 400 includes a satellite receiver unit 402 that receives the positioning information from the GPS satellite 200 via an antenna 401 and a base-station receiving unit 404 that receives the positioning information from the base station apparatus 300 via an antenna 403.

### 3. Moving Object

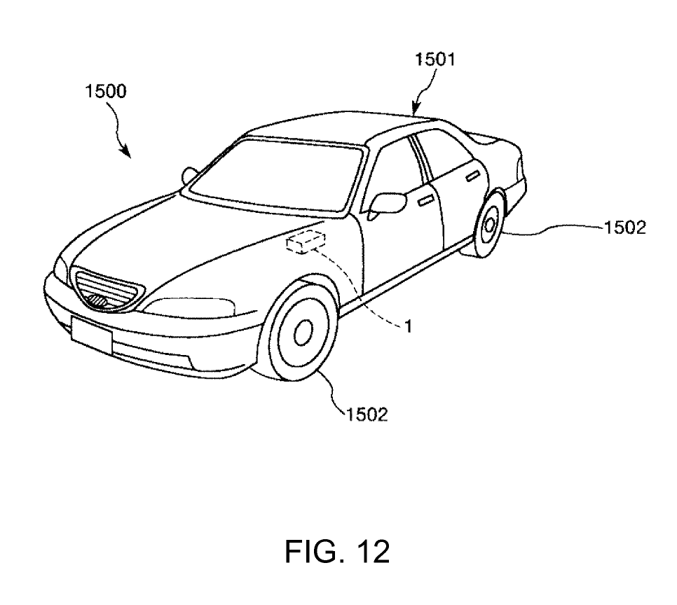

FIG. 12 shows an example of a moving object according to an embodiment of the invention.

In the drawing, a moving object 1500 includes a vehicle body 1501 and a four wheels 1502, and is adapted to turn the wheels 1502 by a power source (engine) (not shown) provided in the vehicle body 1501. The moving object 1500 contains the atomic oscillator 1.

According to the moving object, advantageous reliability may be exhibited.

Note that the electronic apparatus including the atomic oscillator according to the invention (quantum interference device according to the invention) is not limited to the above described apparatus, but e.g., a cell phone, a digital still camera, an inkjet ejection device (for example, an inkjet printer), a personal computer (mobile personal computer, laptop personal computer), a television, a video camera, a video tape recorder, a car navigation system, a pager, a personal digital assistance (with or without communication function), an electronic dictionary, a calculator, an electronic game machine, a word processor, a work station, a videophone, a security television monitor, electronic binoculars, a POS terminal, a medical device (for example, an electronic thermometer, a sphygmomanometer, a blood glucose meter, an electrocardiographic measurement system, an ultrasonic diagnostic system, or an electronic endoscope), a fish finder, various measurement instruments, meters and gauges (for example, meters for vehicles, airplanes, and ships), a flight simulator, digital terrestrial broadcasting, a cellular base station, or the like.

The quantum interference device, the atomic oscillator, the electronic apparatus, and the moving object according to the invention have been explained based on the illustrated embodiments, however, the invention is not limited to those.

Further, in the quantum interference device, the atomic oscillator, the electronic apparatus, and the moving object according to the invention, the configurations of the respective parts may be replaced by arbitrary configurations that exhibit the same functions, or arbitrary configurations may be added thereto.

Furthermore, in the atomic oscillator according to the invention, arbitrary configurations of the above described respective embodiments may be combined.

In addition, in the invention, the structure of the atomic oscillator (quantum interference device) is not limited to the configurations of the above described embodiments as long as the width W1 of the internal space of the gas cell along the direction perpendicular to the axis of the light output from the light output part and the width W2 of the light along the same direction in the internal space of the gas cell satisfy the above described relation.

For example, in the above described embodiments, the structure in which the gas cell is provided between the light output part and the light detection part has been explained as an example, however, the light output part and the light detection part may be provided at the same side with respect to the gas cell, and light reflected by a surface at the opposite side to the light output part and the light detection part of the gas cell or a mirror provided at the opposite side to the light output part and the light detection part of the gas cell may be detected by the light detection part.

Further, in the above described first embodiment, the example in which the first package, the second package, and the optical components are respectively engaged with the through holes formed in the wiring board has been explained, however, not limited to that. For example, the first package, the second package, and the optical components may be provided on one surface of the wiring board or the first package, the second package, and the optical components may be collectively held by a box-shaped or block-shaped holder and the holder may be provided on the wiring board.

The entire disclosure of Japanese Patent Application No. 2013-205755 filed Sep. 30, 2013 is expressly incorporated by reference herein.

What is claimed is:

1. A quantum interference device comprising:
a gas cell having an internal space in which metal atoms are entrapped; and
a light output part that outputs light toward the internal space, the light containing a pair of resonance lights for resonance with the metal atoms,
wherein a width of the internal space along a direction intersecting an axis of the light is W1,
a width of the light along the intersecting direction in the internal space is W2, and
40%≦W2/W1≦95%.

2. The quantum interference device according to claim 1, wherein 55%≦W2/W1≦65%.

3. The quantum interference device according to claim 1, wherein a length of the internal space along an axis direction of the light is L1, and
W1<L1.

4. The quantum interference device according to claim 1, wherein a distance between a wall surface of the internal space along the intersecting direction and the light is 0.25 mm or more.

5. The quantum interference device according to claim 4, wherein W1 is within a range from 1 mm to 10 mm.

6. The quantum interference device according to claim 4, wherein L1 is within a range from 3 mm to 30 mm.

7. The quantum interference device according to claim 1, further comprising a diaphragm unit between the light output part and the internal space.

8. The quantum interference device according to claim 7, further comprising a coil that generates a magnetic field in the axis direction of the light in the internal space.

9. The quantum interference device according to claim 1, wherein a radiation angle of the light output from the light output part is θ,
a distance between the light output part and the gas cell is L, and
L×tan (θ/2) is within a range from 0.2 mm to 5.0 mm.

10. An atomic oscillator comprising the quantum interference device according to claim 1.

11. An electronic apparatus comprising the quantum interference device according to claim 1.

12. A moving object comprising the quantum interference device according to claim 1.

13. A quantum interference device comprising:
a gas cell having an internal space in which metal atoms are entrapped, the internal space having a width W1 in a first direction; and
a light source emitting light toward the internal space for resonance with the metal atoms, the light having a width W2 in the first direction,
wherein the first direction is orthogonal to a propagating direction of the light, and
40%≦W2/W1≦95%.

14. The quantum interference device according to claim 13, wherein 55%≦W2/W1≦65%.

15. The quantum interference device according to claim 13, wherein the internal space has a length L1 in the propagating direction of the light, and
W1<L1.

16. The quantum interference device according to claim 13, further comprising a light diaphragm between the light source and the internal space.

17. The quantum interference device according to claim 16, further comprising a magnetic field generating coil in the internal space.

18. The quantum interference device according to claim 13, wherein the light has a radiation angle θ,
a distance between the light source and the gas cell is L, and
0.2 mm≦(L×tan(θ/2))≦5.0 mm.
